(19) United States
(12) Patent Application Publication
(10) Pub. No.: US 2026/0053049 A1
(43) Pub. Date: Feb. 19, 2026

(54) METHOD FOR MANUFACTURING SEMICONDUCTOR APPARATUS

(71) Applicant: Mitsubishi Electric Corporation, Tokyo (JP)

(72) Inventor: Masaaki SATO, Tokyo (JP)

(73) Assignee: Mitsubishi Electric Corporation, Tokyo (JP)

(21) Appl. No.: 19/103,039

(22) PCT Filed: Oct. 28, 2022
(86) PCT No.: PCT/JP2022/040391

§ 371 Date: Feb. 11, 2025

(51) Int. Cl. H01L 23/00; H01L 21/56

(52) U.S. Cl. CPC H01L 24/83; H01L 21/565; H01L 2224/83862

(57) ABSTRACT

A method for manufacturing a semiconductor apparatus includes the steps of: applying a first adhesive having heat dissipation property and thermosetting property onto each of surfaces of a plurality of devices joined to a surface of a substrate, and thereafter mounting heat dissipation blocks, and performing bonding by heat treatment; applying a second adhesive having heat dissipation property and thermosetting property onto each of surfaces of the heat dissipation blocks, so as to be higher than a height A of a molding resin that seals the devices in a later step; and curing the second adhesives by heat treatment while aligning, by using thicknesses of the second adhesives, heights to surfaces of the second adhesives so that the heights are matched with the height A of the molding resin.

### TECHNICAL FIELD

The present disclosure relates to a method for manufacturing a semiconductor apparatus.

### BACKGROUND ART

In a hybrid module applicable to a high-frequency product, which is one example of a conventional semiconductor apparatus, the height of a heat dissipation block is adjusted to expose the dissipation block on a module surface at the time of sealing with a molding resin. By bringing one side of the heat dissipation block into contact with a device which generates heat during operation, with a high-dissipation adhesive interposed therebetween, and by exposing the other side on the module surface, the heat generated from the device can be easily dissipated to the outside of the module.

For example, Patent Document 1 discloses a method for manufacturing a semiconductor apparatus in which a heat dissipation block has one side coming into contact with the back surface of a die stage portion on which a semiconductor element is mounted, and has the other side exposed on a module surface, so that the outer peripheral side surface is surrounded with a resin.

### CITATION LIST

### Patent Document

Patent Document 1: Japanese Laid-Open Patent Publication No. 4-299848 (paragraph [0011], FIG. 1)

### SUMMARY OF THE INVENTION

### Problem to be Solved by the Invention

However, in a conventional method for manufacturing a semiconductor apparatus, it is difficult to precisely make uniform the heights of surfaces of a plurality of heat dissipation blocks due to the dimensional tolerance of the thickness of the heat dissipation blocks and the joining state to an organic substrate. If the height of a heat dissipation block surface is higher than expected, a molding mold and the heat dissipation block come into contact with each other when the molding mold is clamped for molding-resin sealing, resulting in breaking the device by a mold-clamping pressure of the molding mold. If the height of a heat dissipation block surface is lower than expected, the molding resin lies over the heat dissipation block, resulting in deteriorating heat dissipation property of the device.

The present disclosure has been made to solve the above problem, and an object of the present disclosure is to provide a method for manufacturing a semiconductor apparatus in which the heights of surfaces of heat dissipation blocks are precisely made uniform, and the heat dissipation blocks are exposed on a module surface without damaging devices.

### Means to Solve the Problem

A method for manufacturing a semiconductor apparatus according to the present disclosure includes the steps of: applying a first adhesive having heat dissipation property and thermosetting property onto each of surfaces of a plurality of devices joined to a surface of a substrate, and thereafter mounting heat dissipation blocks, and performing bonding by heat treatment; applying a second adhesive having heat dissipation property and thermosetting property onto each of surfaces of the heat dissipation blocks, so as to be higher than a height of a resin that seals the devices in a later step; and curing the second adhesives by heat treatment while aligning, by using thicknesses of the second adhesives, heights to surfaces of the second adhesives so that the heights are matched with the height of the resin.

Another method for manufacturing a semiconductor apparatus according to the present disclosure includes the steps of: applying an adhesive having heat dissipation property and thermosetting property onto each of surfaces of a plurality of devices joined to a surface of a substrate, so as to be, when heat dissipation blocks are mounted, higher than a height of a resin that seals the devices in a later step, and thereafter mounting the heat dissipation blocks; and curing the adhesives by heat treatment while aligning, by using thicknesses of the adhesives, heights to surfaces of the heat dissipation blocks so that the heights are matched with the height of the resin.

### Effect of the Invention

According to the present disclosure, heat dissipation blocks can be exposed on a module surface without damaging devices by precisely making uniform the heights of the heat dissipation block surfaces, and thus, a high performance semiconductor apparatus can be easily obtained.

### BRIEF DESCRIPTION OF THE DRAWINGS

FIG. 1 is a flowchart showing a manufacturing process in a method for manufacturing a semiconductor apparatus according to embodiment 1.

FIG. 2 is a sectional view showing the manufacturing process in the method for manufacturing the semiconductor apparatus according to embodiment 1.

FIG. 3 is a flowchart showing a manufacturing process in a method for manufacturing a semiconductor apparatus according to embodiment 2.

FIG. 4 is a sectional view showing the manufacturing process in the method for manufacturing the semiconductor apparatus according to embodiment 2.

FIG. 5 is a flowchart showing a manufacturing process in a method for manufacturing a semiconductor apparatus according to embodiment 3.

FIG. 6 is a sectional view showing the manufacturing process in the method for manufacturing the semiconductor apparatus according to embodiment 3.

FIG. 7 is a flowchart showing a manufacturing process in a method for manufacturing a semiconductor apparatus according to embodiment 4.

FIG. 8 is a sectional view showing the manufacturing process in the method for manufacturing the semiconductor apparatus according to embodiment 4.

### DESCRIPTION OF EMBODIMENTS

### Embodiment 1

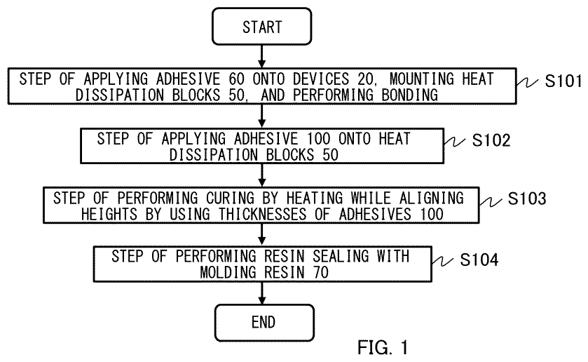

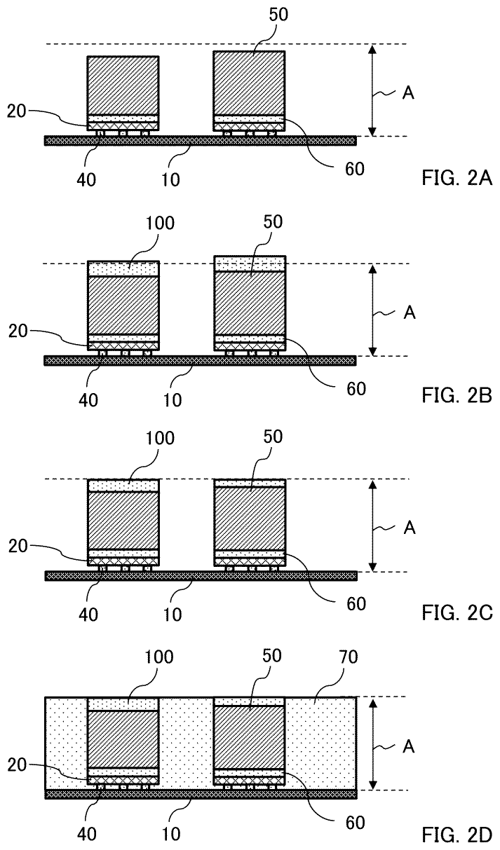

FIG. 1 is a flowchart showing a manufacturing process in a method for manufacturing a semiconductor apparatus according to embodiment 1 of the present disclosure. FIG. 2 is a sectional view showing the manufacturing process in the method for manufacturing the semiconductor apparatus according to embodiment 1 of the present disclosure. FIG. 2(a) is a sectional view of the semiconductor apparatus after mounting heat dissipation blocks on devices on an organic substrate and performing heat treatment. FIG. 2(b) is a sectional view of the semiconductor apparatus after applying an adhesive onto each of the heat dissipation blocks. FIG. 2(c) is a sectional view of the semiconductor apparatus after heat treating the adhesives applied on the heat dissipation blocks. FIG. 2(d) is a sectional view of the semiconductor apparatus after sealing with a molding resin.

First, as shown in FIG. 2(a), an adhesive 60, which is a first adhesive having high heat dissipation property and thermosetting property, is applied onto each of a plurality of devices 20 joined to an organic substrate 10 by means of solders 40, and thereafter, heat dissipation blocks are mounted, and bonding is performed through curing of the adhesives 60 by heat treatment (step S101). The heights of the heat dissipation blocks 50 after the bonding are set to be lower than a height A of a package. At this time, variation in height at the upper parts of the heat dissipation blocks 50 occurs due to the dimensional tolerances of the thicknesses of the organic substrate 10, the solders 40, the devices 20, the adhesives 60, and the heat dissipation blocks 50, and the joining state at the organic substrate.

Next, as shown in FIG. 2(b), an adhesive 100, which is a second adhesive having high heat dissipation property and thermosetting property, is applied onto each of the heat dissipation blocks 50, so as to be higher than the height A of the package (step S102).

Subsequently, as shown in FIG. 2(c), the adhesives 100 are cured by heat treatment while the heights to the adhesives 100 applied on the heat dissipation blocks 50 on all the devices 20 are aligned by using the thicknesses of the adhesives 100, through clamping with a jig, so that the heights are matched with the height A of the package (step S103).

Finally, as shown in FIG. 2(d), resin sealing of the devices 20 is performed with a molding resin 70 so as to reach the height A of the package (step S104), whereby the surfaces of the adhesives 100 are exposed on the upper surface of the package (molding resin 70). At this time, the surfaces of the adhesives 100 are brought into contact with a molding mold with a protective tape or the like interposed therebetween, whereby the molding resin 70 is prevented from flowing onto the adhesives 100.

Here, since the devices 20 are joined by flip chip and are electrically connected from the lower surfaces of the devices 20, electrical conduction at the upper surfaces of the devices 20 is not needed, and the adhesive 60 and the adhesive 100 may be either electrically conductive adhesives or insulating adhesives.

As described above, a method for manufacturing a semiconductor apparatus according to the present embodiment 1 includes the steps of: applying an adhesive 60 having heat dissipation property and thermosetting property onto each of surfaces of a plurality of devices 20 joined to a surface of an organic substrate 10, and thereafter mounting heat dissipation blocks 50, and performing bonding by heat treatment; applying an adhesive 100 having heat dissipation property and thermosetting property onto each of surfaces of the heat dissipation blocks 50, so as to be higher than a height A of a molding resin 70 that seals the devices 20 in a later step; and curing the adhesives 100 by heat treatment while aligning, by using thicknesses of the adhesives 100, heights from the surface of the organic substrate 10 to surfaces of the adhesives 100 so that the heights are matched with the height A of the molding resin 70. Thus, through leveling by using the thicknesses of the adhesives 100 so that the heights from the organic substrate 10 to the adhesives 100 become the same as the package height A, variation due to the dimensional tolerances of the thicknesses of the organic substrate, the solders, the devices, the first adhesive, and the heat dissipation blocks, and the joining state at the organic substrate, can be absorbed. By precisely making uniform the heights of heat dissipation parts, the heat dissipation parts can be exposed on a module surface without damaging devices. Therefore, a high performance semiconductor apparatus can be easily obtained.

Accordingly, the heights of the second adhesives are prevented from being higher than the height A of the package, whereby the second adhesives are prevented from coming into contact with the molding mold at the time of molding-resin sealing, and thus, the devices are prevented from being broken by a mold-clamping pressure of the molding mold.

In addition, the heights of the second adhesives are prevented from being lower than the height A of the package, whereby the molding resin is prevented from flowing onto the upper parts of the heat dissipation blocks. Furthermore, as compared with conventional methods, cutting steps can be reduced, and quality defects, such as production of burrs at heat dissipation blocks and chipping of a molding resin, can be prevented from easily occurring.

### Embodiment 2

While the step of heat treating and curing the adhesives 100 is performed independently in embodiment 1, a case of performing the step simultaneously with the step of resin-sealing the devices 20 will be described in embodiment 2.

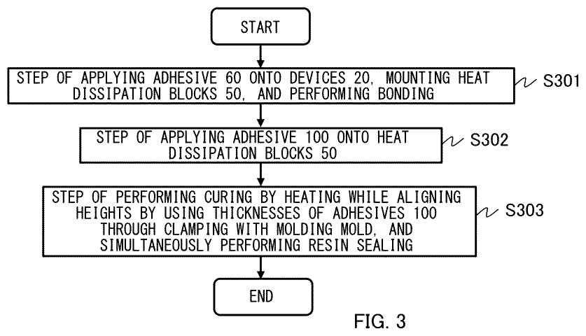

FIG. 3 is a flowchart showing a manufacturing process in a method for manufacturing a semiconductor apparatus according to embodiment 2 of the present disclosure. FIG. 3 is a sectional view showing the manufacturing process in the method for manufacturing the semiconductor apparatus according to embodiment 2 of the present disclosure. FIG. 3(a) is a sectional view showing the semiconductor apparatus after mounting heat dissipation blocks on devices on an organic substrate and performing heat treatment. FIG. 3(b) is a sectional view showing the semiconductor apparatus after applying an adhesive onto each of the heat dissipation blocks. FIG. 3(c) is a sectional view showing the semiconductor apparatus after curing the adhesives and simultaneously performing sealing with a molding resin.

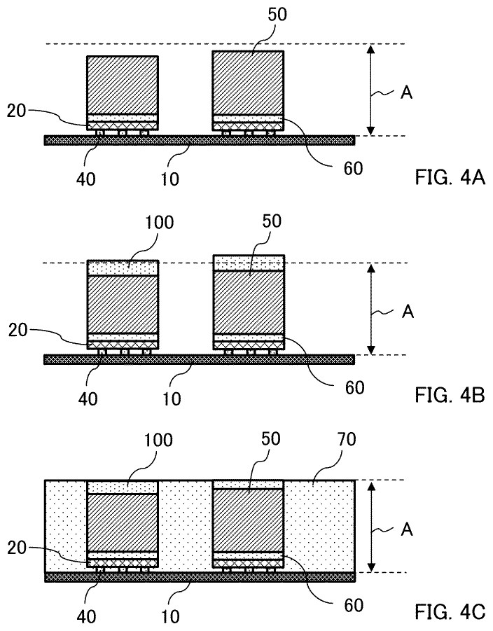

In the present embodiment 2, the method for manufacturing the semiconductor apparatus in the process from step S301 (FIG. 4(a)) to step S302 (FIG. 4(b)) in FIG. 3 is the same as the method for manufacturing the semiconductor apparatus in the process from step S101 (FIG. 2(a)) to step S102 (FIG. 2(b)) in FIG. 1 in embodiment 1, and corresponding parts are denoted by the same reference characters and the description thereof is omitted.

After step S302, the step of heat treating the adhesives 100 is not performed independently in embodiment 2, but, in a clamped state by a molding mold with the adhesives 100 uncured, as shown in FIG. 4(c), while the heights to the adhesives 100 applied on the heat dissipation blocks 50 on all the devices 20 are aligned by using the thicknesses of the adhesives 100 so that the heights are matched with a height A of a package, the adhesives 100 are cured by heat treatment, and simultaneously, the devices 20 are sealed with a molding resin 70 (step S303) so that the adhesives 100 are exposed on the upper surface of the package (molding resin 70). At this time, a protective tape or the like is interposed between the molding mold and the adhesives 100 to prevent bonding between the molding mold and the adhesives 100.

Here, since the devices 20 are joined by flip chip and are electrically connected from the lower surfaces of the devices 20, electrical conduction at the upper surfaces of the devices 20 is not needed, and the adhesive 60 and the adhesive 100 may be either electrically conductive adhesives or insulating adhesives.

As described above, a method for manufacturing a semiconductor apparatus according to the present embodiment 2 includes the steps of: applying an adhesive 60 having heat dissipation property and thermosetting property onto each of surfaces of a plurality of devices 20 joined to a surface of an organic substrate 10, and thereafter mounting heat dissipation blocks 50, and performing bonding by heat treatment; applying an adhesive 100 having heat dissipation property and thermosetting property onto each of surfaces of the heat dissipation blocks 50, so as to be higher than a height A of a molding resin 70 that seals the devices 20 in a later step; and curing the adhesives 100 by heat treatment while aligning, by using thicknesses of the adhesives 100, heights from the surface of the organic substrate 10 to surfaces of the adhesives 100 so that the heights are matched with the height A of the molding resin 70. The step of curing the adhesives 100 includes curing the adhesives 100 by heat treatment while aligning the heights through clamping with a molding mold, and simultaneously sealing the devices 20 with the molding resin 70. Therefore, it is possible not only to obtain the effects of embodiment 1 but also to reduce steps because it is unnecessary to perform heat treatment on the second adhesive independently.

### Embodiment 3

While the thickness of the adhesive 100 is used for matching heights with the height of the package in embodiment 1 and embodiment 2, a case of using the thickness of the adhesive 60 for matching heights with the height of the package will be described in embodiment 3.

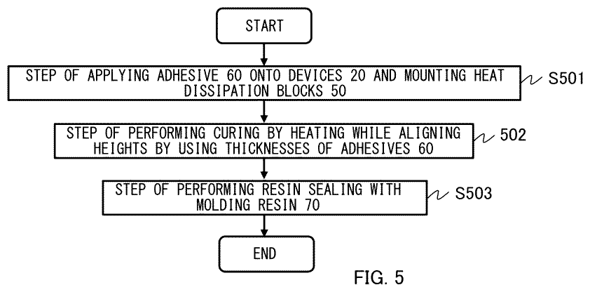

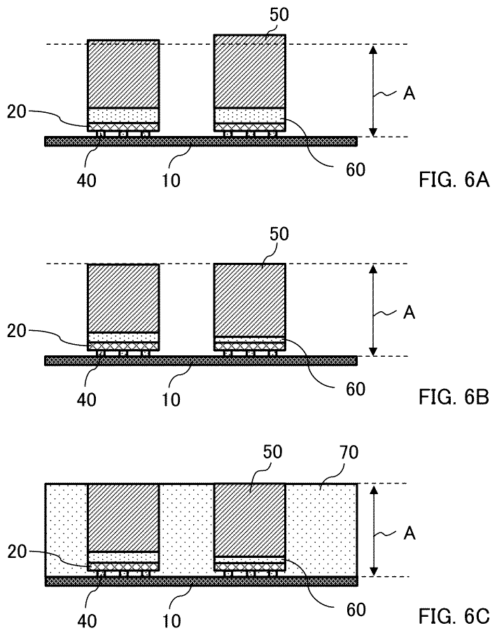

FIG. 5 is a flowchart showing a manufacturing process in a method for manufacturing a semiconductor apparatus according to embodiment 3 of the present disclosure. FIG. 6 is a sectional view showing the manufacturing process in the method for manufacturing the semiconductor apparatus according to embodiment 3 of the present disclosure. FIG. 6(a) is a sectional view showing the semiconductor apparatus after mounting heat dissipation blocks on devices on an organic substrate. FIG. 6(b) is a sectional view showing the semiconductor apparatus after heat treating adhesives on which the heat dissipation blocks are mounted. FIG. 6(c) is a sectional view of the semiconductor apparatus after performing sealing with a molding resin.

First, as shown in FIG. 6(a), an adhesive 60 having high heat dissipation property and thermosetting property is thickly applied onto each of a plurality of devices 20 joined to an organic substrate 10 by means of solders 40, and thereafter, heat dissipation blocks are mounted (step S501). The heights after mounting the heat dissipation blocks 50 are set to be higher than a height A of a package by the amounts corresponding to the thickly applied adhesives 60. At this time, variation in height at the upper parts of the heat dissipation blocks 50 occurs due to the dimensional tolerances of the thicknesses of the organic substrate 10, the solders 40, the devices 20, the adhesives 60, and the heat dissipation blocks 50, and the joining state at the organic substrate.

Next, as shown in FIG. 6(b), the adhesives 100 are cured by heat treatment while the heights to the heat dissipation blocks 50 on all the devices 20 are aligned by using the thicknesses of the adhesives 60, through clamping with a jig, so that the heights are matched with the height A of the package (step S502).

Finally, as shown in FIG. 6(c), the devices 20 are sealed with a molding resin 70 so as to be matched with the height A of the package (step S503), so that the surfaces of the heat dissipation blocks 50 are exposed on the upper surface of the package (molding resin 70). At this time, the surfaces of the heat dissipation blocks 50 are brought into contact with a molding mold with a protective tape or the like interposed therebetween, and thus, the molding resin 70 is prevented from flowing onto the heat dissipation blocks 50.

Here, since the devices 20 are joined by flip chip and are electrically connected from the lower surfaces of the devices 20, electrical conduction at the upper surfaces of the devices 20 is not needed, and the adhesive 60 may be either an electrically conductive adhesive or an insulating adhesive.

As described above, a method for manufacturing a semiconductor apparatus according to the present embodiment 3 includes the steps of: applying an adhesive 60 having heat dissipation property and thermosetting property onto each of surfaces of a plurality of devices 20 joined to a surface of an organic substrate 10, so as to be, when heat dissipation blocks 50 are mounted, higher than a height of a molding resin 70 that seals the devices 20 in a later step, and thereafter mounting the heat dissipation blocks 50; and curing the adhesives 60 by heat treatment while aligning, by using thicknesses of the adhesives 60, heights from the surface of the organic substrate 10 to surfaces of the heat dissipation blocks 50 so that the heights are matched with the height A of the molding resin 70. Thus, through leveling by using the thicknesses of the adhesives 60 so that the heights from the organic substrate 10 to the heat dissipation blocks 50 become the same as the height A of the molding resin 70, variation due to the dimensional tolerances of the thicknesses of the organic substrate, the solders, the devices, the adhesives, and the heat dissipation blocks, and the joining state at the organic substrate can be absorbed. By precisely making uniform the heights of the heat dissipation block surfaces, the heat dissipation blocks can be exposed on the module surface without damaging the devices. Therefore, a high performance semiconductor apparatus can be easily obtained.

Accordingly, the heights of the heat dissipation blocks are prevented from being higher than the height A of the package, whereby the heat dissipation blocks are prevented from coming into contact with the molding mold at the time of molding-resin sealing, and thus, the devices are prevented from being broken by a mold-clamping pressure of the molding mold.

In addition, the heights of the adhesives are prevented from being lower than the height A of the package, whereby the molding resin is prevented from flowing onto the upper parts of the heat dissipation blocks. Furthermore, as compared with conventional methods, cutting steps can be reduced, and quality defects, such as production of burrs at heat dissipation blocks and chipping of a molding resin, can be prevented from easily occurring.

### Embodiment 4

While the step of heat treating and curing the adhesive 60 is performed independently in embodiment 3, a case of performing the step simultaneously with the step of resin-sealing the devices 20 will be described in embodiment 4.

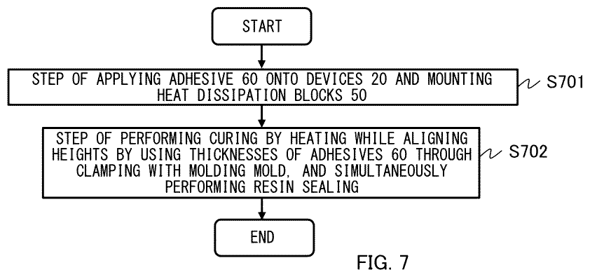

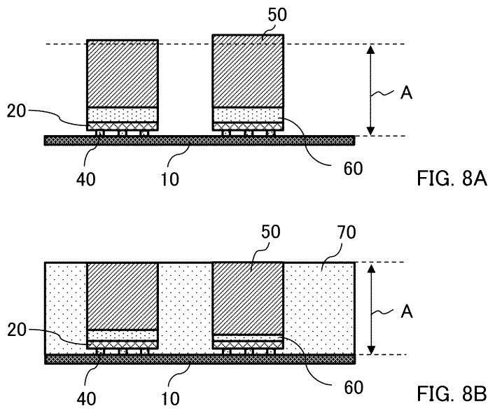

FIG. 7 is a flowchart showing a manufacturing process in a method for manufacturing a semiconductor apparatus according to embodiment 4 of the present disclosure. FIG. 8 is a sectional view showing the manufacturing process in the method for manufacturing the semiconductor apparatus according to embodiment 4 of the present disclosure. FIG. 8(a) is a sectional view showing the semiconductor apparatus after mounting heat dissipation blocks on devices on an organic substrate. FIG. 8(b) is a sectional view of the semiconductor apparatus after curing an adhesive and simultaneously performing sealing with a molding resin.

In the present embodiment 4, the method for manufacturing the semiconductor apparatus in the processing of step S701 (FIG. 8(a)) in FIG. 7 is the same as the method for manufacturing the semiconductor apparatus in the processing of step S501 (FIG. 6(a)) in FIG. 5 in embodiment 3, and corresponding parts are denoted by the same reference characters and the description thereof is omitted.

After step S701, the step of heat treating the adhesives 60 is not performed independently in embodiment 4, but, in a clamped state by a molding mold with the adhesives 60 uncured, as shown in FIG. 8(b), while all the heights to the tops of the heat dissipation blocks 50 on the devices 20 are aligned by using the thicknesses of the adhesives 60 so that the heights are matched with a height A of a package, the adhesives 60 are cured by heat treatment, and simultaneously, the devices 20 are sealed with a molding resin 70 (step S802), so that the surfaces of the heat dissipation blocks 50 are exposed on the upper surface of the package (molding resin 70). At this time, the surfaces of the heat dissipation blocks 50 are brought into contact with the molding mold with a protective tape or the like interposed therebetween, and thus, the molding resin 70 is prevented from flowing onto the heat dissipation blocks 50.

Here, since the devices 20 are joined by flip chip and are electrically connected from the lower surfaces of the devices 20, electrical conduction at the upper surfaces of the devices 20 is not needed, and the adhesive 60 may be either an electrically conductive adhesive or an insulating adhesive.

As described above, a method for manufacturing a semiconductor apparatus according to the present embodiment 4 includes the steps of: applying an adhesive 60 having heat dissipation property and thermosetting property onto each of surfaces of a plurality of devices 20 joined to a surface of an organic substrate 10, so as to be, when heat dissipation blocks 50 are mounted, higher than a height of a molding resin 70 that seals the devices 20 in a later step, and thereafter mounting the heat dissipation blocks 50; and curing the adhesives 60 by heat treatment while aligning, by using thicknesses of the adhesives 60, heights from the surface of the organic substrate 10 to surfaces of the heat dissipation blocks 50 so that the heights are matched with the height A of the molding resin 70. The step of curing the adhesives 60 includes curing the adhesives 60 by heat treatment while aligning the heights through clamping with a molding mold, and simultaneously sealing the devices 20 with the molding resin 70. Therefore, it is possible not only to obtain the effects of embodiment 3 but also to reduce steps because it is unnecessary to perform heat treatment on the adhesive independently.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure. It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

10 organic substrate
20 device
40 solder
50 heat dissipation block
60 adhesive
70 molding resin
100 adhesive

1. A method for manufacturing a semiconductor apparatus, the method comprising the steps of:
applying a first adhesive having heat dissipation property and thermosetting property onto each of surfaces of a plurality of devices joined to a surface of a substrate, and thereafter mounting heat dissipation blocks, and performing bonding by heat treatment;
applying a second adhesive having heat dissipation property and thermosetting property onto each of surfaces of the heat dissipation blocks, so as to be higher than a height of a resin that seals the devices in a later step; and
curing the second adhesives by heat treatment while aligning, by using thicknesses of the second adhesives, heights to surfaces of the second adhesives so that the heights are matched with the height of the resin.

2. The method for manufacturing the semiconductor apparatus according to claim 1, wherein the step of curing the second adhesives includes curing the second adhesives by heat treatment while aligning the heights through clamping with a mold, and simultaneously sealing the devices with the resin.

3. A method for manufacturing a semiconductor apparatus, the method comprising the steps of:
applying an adhesive having heat dissipation property and thermosetting property onto each of surfaces of a plurality of devices joined to a surface of a substrate, so as to be, when heat dissipation blocks are mounted, higher than a height of a resin that seals the devices in a later step, and thereafter mounting the heat dissipation blocks; and
curing the adhesives by heat treatment while aligning, by using thicknesses of the adhesives, heights to surfaces of the heat dissipation blocks so that the heights are matched with the height of the resin.

4. The method for manufacturing the semiconductor apparatus according to claim 3, wherein the step of curing the adhesives includes curing the adhesives by heat treatment while aligning the heights through clamping with a mold, and simultaneously sealing the devices with the resin.
